(19) United States
(12) Patent Application Publication
(10) Pub. No.: US 2025/0038730 A1
(43) Pub. Date: Jan. 30, 2025

(54) ACOUSTIC WAVE DEVICE

(71) Applicant: Murata Manufacturing Co., Ltd., Nagaokakyo-shi (JP)

(72) Inventors: Munehisa WATANABE, Nagaokakyo-shi (JP); Kazunori INOUE, Nagaokakyo-shi (JP)

(21) Appl. No.: 18/918,786

(22) Filed: Oct. 17, 2024

Related U.S. Application Data
(63) Continuation of application No. PCT/JP2023/015798, filed on Apr. 20, 2023.
(60) Provisional application No. 63/333,307, filed on Apr. 21, 2022.

(51) Int. Cl. H03H 9/02; H03H 9/13; H03H 9/17; H03H 9/56

(52) U.S. Cl. CPC H03H 9/02086; H03H 9/02031; H03H 9/02157; H03H 9/02228; H03H 9/13; H03H 9/173; H03H 9/176; H03H 9/562; H03H 9/564; H03H 9/568

(57) ABSTRACT

An acoustic wave device includes acoustic wave resonators including one or more series arm resonators and one or more parallel arm resonators. The acoustic wave resonators include a support including a support substrate with a thickness in a first direction, a piezoelectric layer in the first direction of the support, an IDT electrode on one principal surface of the piezoelectric layer, a first dielectric film on the one principal surface, and a second dielectric film on the first dielectric film. A thickness of one of the first dielectric films is larger than a thickness of another one of the first dielectric films. A thickness of one of the second dielectric films is smaller than a thickness of another one of the second dielectric films.

### CROSS REFERENCE TO RELATED APPLICATIONS

This application claims the benefit of priority to Provisional Application No. 63/333,307 filed on Apr. 21, 2022 and is a Continuation Application of PCT Application No. PCT/JP2023/015798 filed on Apr. 20, 2023. The entire contents of each application are hereby incorporated herein by reference.

### BACKGROUND OF THE INVENTION

### 1. Field of the Invention

The present disclosure relates to acoustic wave devices that each include a piezoelectric layer.

### 2. Description of the Related Art

For example, an acoustic wave device described in Japanese Unexamined Patent Application Publication No. 2012-257019 includes a support body, a piezoelectric substrate, and an IDT electrode. The acoustic wave device is disclosed in which the support body is provided with a hollow portion. The piezoelectric substrate is provided on the support body to overlap the hollow portion. The IDT electrode is provided on the piezoelectric substrate to overlap the hollow portion. In the acoustic wave device of Japanese Unexamined Patent Application Publication No. 2012-257019, a plate wave is excited by the IDT electrode.

In recent years, there has been a demand for an acoustic wave device that can reduce or prevent deterioration in characteristics.

### SUMMARY OF THE INVENTION

Example embodiments of the present invention provide acoustic wave devices each with reduced or prevented deterioration in characteristics.

An acoustic wave device according to an example embodiment of the present invention includes an input terminal, an output terminal, a series arm electrically connected between the input terminal and the output terminal, at least one parallel arm electrically connected between the series arm and a ground potential, and acoustic wave resonators including one or more series arm resonators located at the series arm and one or more parallel arm resonators located at the parallel arm. The acoustic wave resonators include a support including a support substrate having a thickness in a first direction, a piezoelectric layer extending in the first direction of the support, an IDT electrode on one principal surface in the first direction of the piezoelectric layer, a first dielectric film on the one principal surface of the piezoelectric layer, and a second dielectric film on the first dielectric film. A thickness of one of the first dielectric film of the series arm resonator and the first dielectric film of the parallel arm resonator is larger than a thickness of another one of the first dielectric film of the series arm resonator and the first dielectric film of the parallel arm resonator. A thickness of one of the second dielectric film of the series arm resonator and the second dielectric film of the parallel arm resonator is smaller than a thickness of another one of the second dielectric film of the series arm resonator and the second dielectric film of the parallel arm resonator.

According to example embodiments of the present invention, it is possible to provide acoustic wave devices each with reduced or prevented deterioration in characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating external appearance of an acoustic wave device according to an example embodiment of the present invention.

FIG. 1B is a plan view illustrating an electrode structure on a piezoelectric layer according to an example embodiment of the present invention.

FIG. 2 is a cross-sectional view of a portion taken along the A-A line in FIG. 1A.

FIG. 3A is a schematic elevational cross-sectional view for explaining a Lamb wave that propagates in a piezoelectric film of an acoustic wave device of the related art.

FIG. 3B is a schematic elevational cross-sectional view for explaining a wave in an acoustic wave device according to an example embodiment of the present invention.

FIG. 4 is a schematic diagram illustrating a bulk wave in a case in which a voltage is applied between a first electrode and a second electrode, which brings about a higher potential voltage at the second electrode than that at the first electrode.

FIG. 5 is a diagram illustrating resonance characteristics of an acoustic wave device according to a first example embodiment of the present invention.

FIG. 6 is a diagram illustrating a relationship between d/2p and a fractional bandwidth as a resonator of the acoustic wave device according to the first example embodiment of the present invention.

FIG. 7 is a plan view of another acoustic wave device according to the first example embodiment of the present invention.

FIG. 8 is a reference diagram illustrating an example of the resonance characteristics of the acoustic wave device according to the first example embodiment of the present invention.

FIG. 9 is a diagram illustrating a relationship between a fractional bandwidth and a phase rotation amount of impedance of a spurious response normalized by about 180 degrees as magnitude of the spurious when a large number of acoustic wave resonators are provided.

FIG. 10 is a diagram illustrating a relationship among d/2p, a metallization ratio MR, and the fractional bandwidth.

FIG. 11 is a diagram illustrating a map of the fractional bandwidth relative to Euler angles (0°, θ, ψ) of LiNbO₃ when d/p is as close to 0 as possible.

FIG. 12 is a partial cutout perspective view for explaining the acoustic wave device according to the first example embodiment of the present invention.

FIG. 13 is a circuit diagram of the acoustic wave device.

FIG. 14 is a cross-sectional view schematically illustrating a layer structure of a portion of an acoustic wave resonator in an acoustic wave device of the related art.

FIG. 15 is a graph depicting log magnitude relative to a frequency in the acoustic wave device of the related art.

FIG. 16 is a Smith chart regarding the acoustic wave device of the related art.

FIG. 17 is a graph depicting the log magnitude relative to the frequency in the acoustic wave device of the related art.

FIG. 18 is a schematic plan view of an acoustic wave device according to a second example embodiment of the present invention.

FIG. 19 is a circuit diagram of the acoustic wave device according to the second example embodiment of the present invention.

FIG. 20 is an enlarged view of a portion surrounded by a dash-dotted line in FIG. 18.

FIG. 21 is a cross-sectional view schematically illustrating the acoustic wave device illustrated in FIG. 20, which is taken along the A-A line.

FIG. 22 is a cross-sectional view schematically illustrating a layer structure of a portion of an acoustic wave resonator in the acoustic wave device according to the second example embodiment of the present invention.

FIG. 23 is a cross-sectional view schematically illustrating a layer structure of a portion of an acoustic wave resonator in an acoustic wave device according to a third example embodiment of the present invention.

FIG. 24 is a cross-sectional view schematically illustrating a layer structure of a portion of an acoustic wave resonator in an acoustic wave device according to a fourth example embodiment of the present invention.

FIG. 25 is a cross-sectional view schematically illustrating a layer structure of a portion of an acoustic wave resonator in an acoustic wave device according to a fifth example embodiment of the present invention.

### DETAILED DESCRIPTION OF THE EXAMPLE EMBODIMENTS

Acoustic wave devices according to example embodiments of the present invention include a piezoelectric layer made of lithium niobate or lithium tantalate, for example, and a first electrode and a second electrode facing each other in a direction intersecting with a thickness direction of the piezoelectric layer.

A thickness-shear mode bulk wave is used in an acoustic wave device according to an example embodiment of the present invention.

In an acoustic wave device according to an example embodiment, the first electrode and the second electrode are electrodes located adjacent to each other. When a thickness of the piezoelectric layer is defined as d and a center-to-center distance between the first electrode and the second electrode is defined as p, d/p is set equal to or less than about 0.5, for example. Accordingly, it is possible to increase a Q factor even in the case where size reduction is provided.

In the meantime, a Lamb wave as a plate wave is used in an acoustic wave device according to an example embodiment. Thus, resonance characteristics attributed to the Lamb wave can be obtained.

An acoustic wave device of an example embodiment of the present includes a piezoelectric layer made of lithium niobate or lithium tantalate, for example, and an upper electrode and a lower electrode facing each other in a thickness direction of the piezoelectric layer while interposing the piezoelectric layer therebetween and uses a bulk wave.

The present invention will be clarified below by explaining example embodiments of acoustic wave devices according to the present invention with reference to the drawings.

The example embodiments described in the present specification are illustrative examples and it should be noted that portions of the configurations illustrated in different example embodiments can be substituted for one another or combined with one another.

### First Example Embodiment

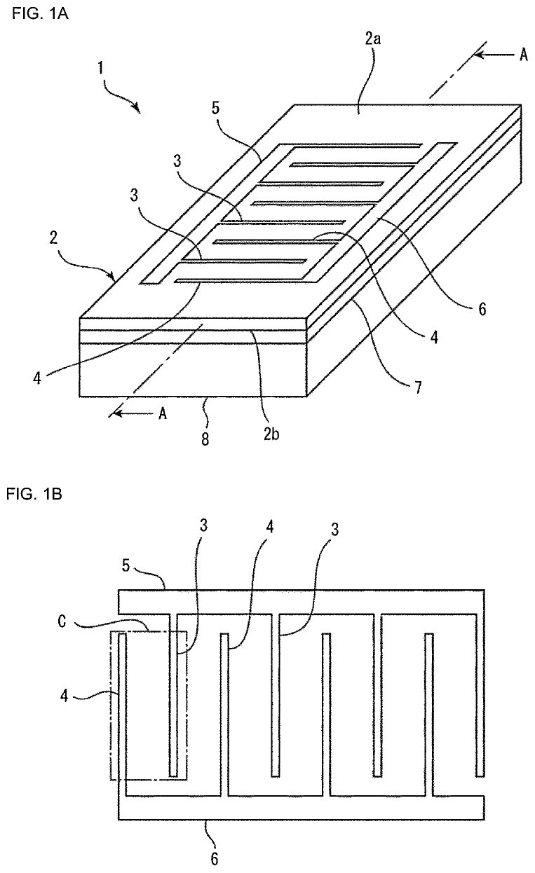

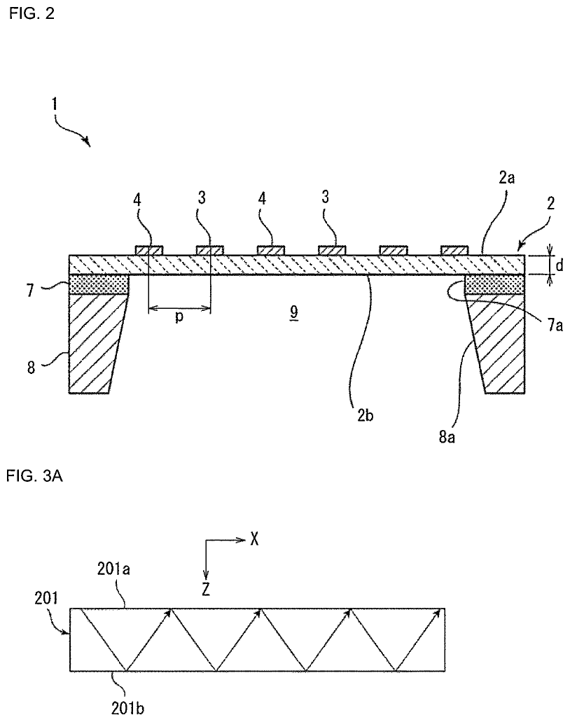

FIG. 1A is a schematic perspective view illustrating external appearance of an acoustic wave device according to a first example embodiment of the present invention. FIG. 1B is a plan view illustrating an electrode structure on a piezoelectric layer. FIG. 2 is a cross-sectional view of a portion taken along the A-A line in FIG. 1A.

An acoustic wave device 1 includes a piezoelectric layer 2 made of, for example, a LiNbO₃. The piezoelectric layer 2 may be made of, for example, LiTaO₃ instead. Cut-angles of LiNbO₃ and LiTaO₃ are provided by Z-cut in the present example embodiment. However, the cut-angles may be provided by rotated Y-cut or X-cut instead. Preferably, for example, a preferred propagation orientation is Y-propagation and X-propagation±about 30°. Although a thickness of the piezoelectric layer 2 is not limited to a particular thickness, the thickness is, for example, preferably set equal to or greater than about 50 nm and equal to or less than about 1000 nm in order to bring about effective excitation in the thickness-shear mode.

The piezoelectric layer 2 includes first and second principal surfaces 2a and 2b facing each other. An electrode 3 and an electrode 4 are provided on the first principal surface 2a. Here, the electrode 3 is an example of a “first electrode” and the electrode 4 is an example of a “second electrode”. In FIGS. 1A and 1B, multiple electrodes 3 are connected to a first busbar 5. Multiple electrodes 4 are connected to a second busbar 6. The electrodes 3 and the electrodes 4 are interdigitated with one another.

The electrodes 3 and the electrodes 4 each have a rectangular or substantially rectangular shape and include a length direction. An electrode 3 and an adjacent electrode 4 face each other in a direction orthogonal or substantially orthogonal to this length direction. The multiple electrodes 3 and 4, the first busbar 5, and the second busbar 6 define interdigital transducer (IDT) electrodes. Each of the length direction of the electrodes 3 and 4 and the direction orthogonal or substantially orthogonal to the length direction of the electrodes 3 and 4 is a direction intersecting with a thickness direction of the piezoelectric layer 2. In this regard, the electrode 3 and the adjacent electrode 4 can also be deemed to face each other in the direction intersecting with the thickness direction of the piezoelectric layer 2.

The length direction of the electrodes 3 and 4 may be interchanged with the direction orthogonal or substantially orthogonal to the length direction of the electrodes 3 and 4 illustrated in FIGS. 1A and 1B. Specifically, the electrodes 3 and 4 may extend in a direction in which the first busbar 5 and the second busbar 6 in FIGS. 1A and 1B extend. In this case, the first busbar 5 and the second busbar 6 extend in a direction in which the electrodes 3 and 4 in FIGS. 1A and 1B extend.

Moreover, pairs of structures each including the electrode 3 connected to one potential and the electrode 4 connected to another potential being located adjacent to each other are provided in the direction orthogonal or substantially orthogonal to the length direction of the electrodes 3 and 4 mentioned above. Here, the state of the electrode 3 and the electrode 4 being located adjacent to each other does not represent a case where the electrode 3 and the electrode 4 are disposed in such a way as to be in direct contact but represents a case where the electrode 3 and the electrode 4 are disposed with a clearance therebetween.

When the electrode 3 and the electrode 4 are located adjacent to each other, electrodes inclusive of other electrodes 3 and electrodes 4 to be connected to a hot electrode or a ground electrode are not disposed between the relevant electrode 3 and the electrode 4. The number of pairs does not always have to be an integer but may also be any of 1.5 pairs, 2.5 pairs, and so forth. A center-to-center distance, that is to say, a pitch between the electrodes 3 and 4 is, for example, preferably in a range from equal to or greater than about 1 μm and equal to or less than about 10 μm. The center-to-center distance between the electrodes 3 and 4 is a distance of connection between the center in a width dimension of the electrode 3 in the direction orthogonal to the length direction of the electrode 3 and the center in a width dimension of the electrode 4 in the direction orthogonal to the length direction of the electrode 4. Moreover, when at least two or more the electrodes 3 or two or more electrodes 4 are present (when there are 1.5 pairs or more of electrode sets assuming that each electrode set includes a pair of the electrode 3 and the electrode 4), the center-to-center distance between the electrodes 3 and 4 is an average value of the respective center-to-center distances of the adjacent electrodes 3 and 4 in the 1.5 pairs or more. The widths of the electrodes 3 and 4, that is to say, dimensions of the electrodes 3 and 4 in a direction in which the electrodes 3 and 4 face each other are, for example, preferably in a range from equal to or greater than about 150 nm and equal to or less than about 1000 nm. Here, the center-to-center distance between the electrodes 3 and 4 is equivalent to a distance of connection between the center in a dimension (the width dimension) of the electrode 3 in the direction orthogonal or substantially orthogonal to the length direction of the electrode 3 and the center in a dimension (the width dimension) of the electrode 4 in the direction orthogonal or substantially orthogonal to the length direction of the electrode 4.

Since the Z-cut piezoelectric layer is used in the present example embodiment, the direction orthogonal or substantially orthogonal to the length direction of the electrodes 3 and 4 is equivalent to a direction orthogonal or substantially orthogonal to a direction of polarization of the piezoelectric layer 2. This is not applicable when a piezoelectric body having a different cut-angle is used as the piezoelectric layer 2. Here, the term “orthogonal” is not limited only to a case of being strictly orthogonal but may also include a case of being substantially orthogonal (where an angle formed between the direction orthogonal to the length direction of the electrodes 3 and 4 and the direction of polarization may be equivalent to about 90°±10°, for example).

A support substrate 8 is laminated on the second principal surface 2b side of the piezoelectric layer 2 while interposing an insulating (intermediate) layer 7 therebetween. The insulating layer 7 and the support substrate 8 define a support. The insulating layer 7 and the support substrate 8 each have a frame shape and include cavities 7a and 8a as illustrated in FIG. 2, and a hollow (space) portion 9 is provided accordingly. The hollow portion 9 is provided in order not to block vibration in an excitation region C of the piezoelectric layer 2. Here, the hollow portion 9 is an example of an energy confinement layer, or may be an acoustic reflection layer as another example. Accordingly, the support substrate 8 is laminated on the second principal surface 2b while interposing the insulating layer 7 therebetween at a position not overlapping a portion where at least a pair of electrodes 3 and 4 are provided. Here, the insulating layer 7 does not always have to be provided. Accordingly, the support substrate 8 may be laminated either directly or indirectly on the second principal surface 2b of the piezoelectric layer 2.

The insulating layer 7 is made of silicon oxide, for example. Nonetheless, an appropriate insulating material such as, for example, silicon oxynitride and alumina can be used in addition to silicon oxide. The support substrate 8 is made of Si, for example. A plane orientation on a surface on the piezoelectric layer 2 side of Si may be (100), (110), or (111). Preferably, for example, high-resistance Si having a resistivity equal to or greater than about 4 kΩ is desired. Nevertheless, the support substrate 8 can also be made using, for example, an insulating material or a semiconductor material as appropriate. For example, as the material of the support substrate 8, it is possible to use piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectric bodies such as diamond and glass, semiconductors such as gallium nitride, and so forth.

The multiple electrodes 3 and 4 as well as the first and second busbars 5 and 6 are made of a metal or an alloy such as, for example, Al and AlCu alloy as appropriate. In the present example embodiment, the electrodes 3 and 4 as well as the first and second busbars 5 and 6 have a structure including an Al film laminated on a Ti film. Here, an adhesion layer other than the Ti film may be used instead.

In driving, an alternating-current voltage is applied between the multiple electrodes 3 and the multiple electrodes 4. To be more precise, the alternating-current voltage is applied between the first busbar 5 and the second busbar 6. Accordingly, it is possible to obtain resonance characteristics by using the thickness-shear mode bulk wave excited in the piezoelectric layer 2.

When the thickness of the piezoelectric layer 2 is defined as d and the center-to-center distance between the electrodes 3 and 4 located adjacent to each other among the multiple pairs of the electrodes 3 and 4 is defined as p in the acoustic wave device 1, d/p is set equal to or less than about 0.5, for example. For this reason, the thickness-shear mode bulk wave can be effectively excited, so that favorable resonance characteristics can be obtained. More preferably, for example, d/p is set equal to or less than about 0.24. In this case, it is possible to obtain even more favorable resonance characteristics.

Here, when at least one of the electrodes 3 and 4 include more than one as in the present example embodiment, or in other words, in the case where the pair of the electrodes 3 and 4 and one of the electrodes 3 and 4 define 1.5 pairs or more, the center-to-center distance p of the electrodes 3 and 4 located adjacent to one another is an average distance between the center-to-center distances of the respective sets of the electrodes 3 and 4 located adjacent to each other.

Since the acoustic wave device 1 of the present example embodiment has the above-described configuration, a drop in Q factor is less likely to occur even when the number of pairs of the electrodes 3 and 4 is decreased in an attempt to reduce size. This is because the acoustic wave device 1 is a resonator which does not require a reflector on each side and causes a small propagation loss. The acoustic wave device 1 does not require the reflectors because the acoustic wave device 1 uses the thickness-shear mode bulk wave.

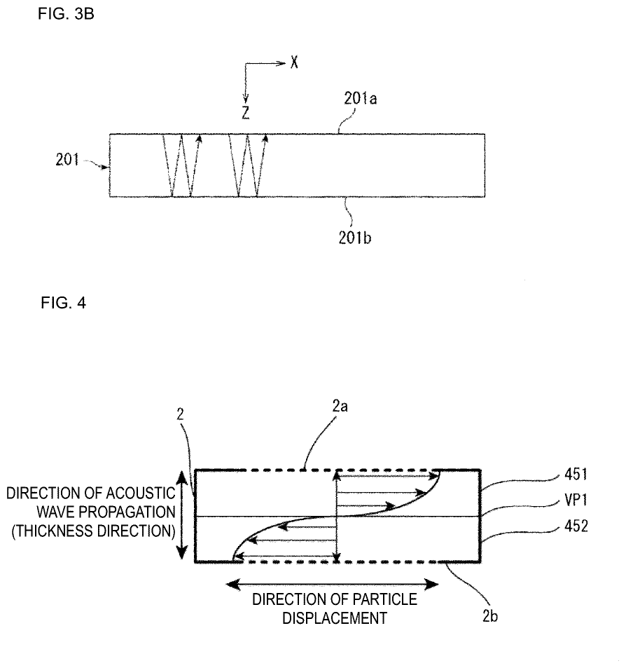

A difference between the Lamb wave used in the acoustic wave device of the related art and the above-described thickness-shear mode bulk wave will be described with reference to FIGS. 3A and 3B.

FIG. 3A is a schematic elevational cross-sectional view for explaining a Lamb wave that propagates in a piezoelectric film of the acoustic wave device of the related art. The acoustic wave device of the related art is disclosed in Japanese Unexamined Patent Application Publication No. 2012-257019, for example. As illustrated in FIG. 3A, in the acoustic wave device of the related art, the wave propagates in a piezoelectric film 201 as indicated by arrows. Here, in the piezoelectric film 201, a first principal surface 201a faces a second principal surface 201b, and a thickness direction connecting the first principal surface 201a to the second principal surface 201b is Z direction. A direction in which electrode fingers of an IDT electrode are arranged is X direction. As illustrated in FIG. 3A, regarding the Lamb wave, the wave propagates in the X direction as illustrated therein. Because of being the plate wave, the piezoelectric film 201 vibrates as a whole. However, since the wave propagates in the X direction, resonance characteristics are obtained by providing reflectors on both sides. This results in wave propagation loss. The Q factor drops in an attempt of size reduction, that is to say, when the number of pairs of the electrode fingers is reduced.

On the other hand, as illustrated in FIG. 3B, vibrational displacement occurs in a thickness-shear direction in the acoustic wave device 1 of the present example embodiment, and the wave therefore propagates and resonates substantially in the direction to connect between the first principal surface 2a and the second principal surface 2b of the piezoelectric layer 2, that is to say, in the Z direction. In other words, an X-direction component of the wave is significantly smaller than a Z-direction component thereof. Moreover, no reflectors are required because the resonance characteristics are obtained by the propagation of the wave in the Z-direction. Therefore, no propagation loss due to propagation through a reflector occurs. Accordingly, a decrease in Q factor is less likely to occur even when the number of pairs of electrode pairs defined by the electrodes 3 and 4 is reduced in an attempt to achieve size reduction.

Here, as illustrated in FIG. 4, a direction of amplitude of the thickness-shear mode bulk wave in a first region 451 included in the excitation region C of the piezoelectric layer 2 is reverse to that in a second region 452 included in the excitation region C. FIG. 4 schematically illustrates the bulk wave in a case in which a voltage is applied between the electrode 3 and the electrode 4, which brings about a higher potential at the electrode 4 than that at the electrode 3. The first region 451 is a region in the excitation region C, which is located between the first principal surface 2a and a virtual plane VP1 that is orthogonal or substantially orthogonal to the thickness direction of the piezoelectric layer 2 and bisects the piezoelectric layer 2. The second region 452 is a region in the excitation region C, which is located between the virtual plane VP1 and the second principal surface 2b.

As described above, at least one pair of electrodes including the electrode 3 and the electrode 4 are disposed in the acoustic wave device 1. However, since the acoustic wave device 1 is not configured to propagate the wave in the X direction, the number of pairs including the electrodes 3 and 4 does not always have to be multiple pairs. That is to say, at least one pair of electrodes needs to be provided therein.

For example, the electrode 3 is an electrode to be connected to a hot potential and the electrode 4 is an electrode to be connected to a ground potential. Nevertheless, the electrode 3 may be connected the ground potential and the electrode 4 may be connected to the hot potential instead. In the present example embodiment, at least the one pair of electrodes includes either the electrode to be connected to the hot potential or the electrode to be connected to the ground potential as mentioned above, and no floating electrodes are provided therein.

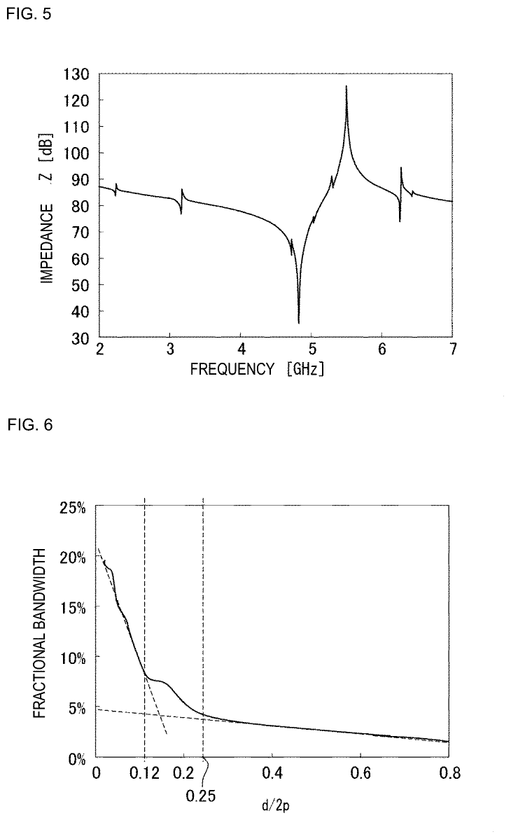

FIG. 5 is a diagram illustrating resonance characteristics of the acoustic wave device according to the first example embodiment of the present invention. Design parameters of the acoustic wave device 1 that obtains these resonance characteristics are as follows:
piezoelectric layer 2: LiNbO₃ having Euler angles (0°, 0°, 90°), a thickness=about 400 nm, a length of a region where the electrode 3 overlaps the electrode 4 when viewed in the direction orthogonal or substantially orthogonal to the length direction of the electrodes 3 and 4, namely, the excitation region C=about 40 μm, the number of pairs of electrodes formed from the electrodes 3 and 4=21 pairs, a center-to-center distance between the electrodes=about 3 μm, a width of the electrodes 3 and 4=500 nm, and d/p=about 0.133
insulating layer 7: a silicon oxide film having a thickness of about 1 μm
support substrate 8: Si

Here, the length of the excitation region C is a dimension of the excitation region C in the length direction of the electrodes 3 and 4.

In the present example embodiment, all of the distances between the electrodes among the electrode pairs including the electrodes 3 and 4 are set equal or substantially equal. In other words, the electrodes 3 and the electrodes 4 are disposed at regular pitches.

As apparent from FIG. 5, favorable resonance characteristics with a fractional bandwidth of about 12.5% are obtained in spite of not being provided with reflectors.

When the thickness of the piezoelectric layer 2 is defined as d and the center-to-center distance of the electrodes between the electrode 3 and the electrode 4 is defined as p, d/p is equal to or less than about 0.5 or more preferably equal to or less than about 0.24 in the present example embodiment as described above. This will be described with reference to FIG. 6.

As with the acoustic wave device that obtained the resonance characteristics depicted in FIG. 5, multiple acoustic wave devices were obtained while changing d/2p thereof. FIG. 6 is a diagram illustrating a relation between d/2p described above and fractional bandwidths as resonators of the acoustic wave devices.

As apparent from FIG. 6, when d/2p exceeds about 0.25, that is to say, when d/p>about 0.5, the fractional bandwidth falls below about 5% even when d/p is adjusted. On the other hand, when d/2p≤about 0.25, that is to say, when d/p≤about 0.5, the fractional bandwidth can be set equal to or greater than about 5% by changing d/p within that range. In other words, it is possible to construct a resonator having a high coupling coefficient. Meanwhile, when d/2p is equal to or less than about 0.12, that is to say, when d/p is equal to or less than about 0.24, the fractional bandwidth can be increased to about 7% or above. In addition, when d/p is adjusted within this range, it is possible to obtain the resonator having an even wider fractional bandwidth and to realize the resonator having an even higher coupling coefficient. Accordingly, it is understood that the resonator having the high coupling coefficient using the above-described thickness-shear mode bulk wave can be constructed by, for example, setting d/p equal to or less than about 0.5 as in the case of the acoustic wave device according to the present example embodiment.

Here, as described above, at least one pair of electrodes may include one pair and the p is defined as the center-to-center distance between the electrodes 3 and 4 that are located adjacent to each other in the case of one pair of electrodes. Meanwhile, in the case of the electrodes of 1.5 pairs or more, an average distance of the center-to-center distances of the electrodes 3 and 4 that are located adjacent to one another may be defined as p.

Regarding the thickness d of the piezoelectric layer as well, a value obtained by averaging thicknesses may be used in a case where the piezoelectric layer 2 has variations in thickness.

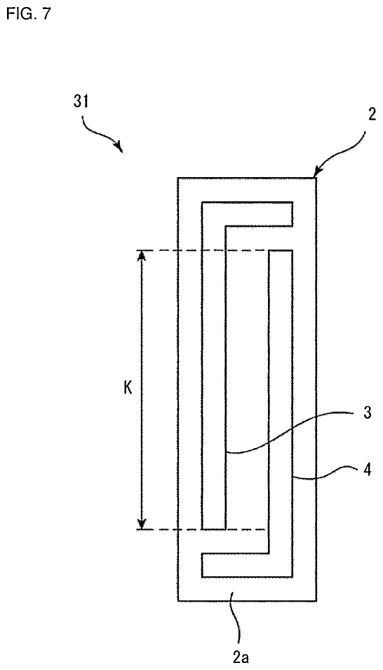

FIG. 7 is a plan view of another acoustic wave device according to the first example embodiment of the present invention. In an acoustic wave device 31, a pair of electrodes including the electrode 3 and the electrode 4 are provided on the first principal surface 2a of the piezoelectric layer 2. Here, reference sign K in FIG. 7 represents an intersecting width. As described above, in the acoustic wave device 31 of the present example embodiment, the number of pairs of electrodes may be one pair. In this case as well, the thickness-shear mode bulk wave can be effectively excited as long as d/p is equal to or less than about 0.5, for example.

Preferably, in the acoustic wave device 1, a metallization ratio MR of certain electrodes 3 and 4 that are located adjacent to each other among the multiple electrodes 3 and 4 relative to the excitation region, which is the region where the electrodes 3 and 4 being located adjacent to each other overlap when viewed in a direction in which the electrodes 3 and 4 face each other, preferably satisfies, for example, MR≤about 1.75(d/p)+0.075. Specifically, the region where the first electrode fingers and the second electrode fingers being located adjacent to one another overlap when viewed in the direction in which the first electrode fingers and the second electrode fingers face each other is the excitation region (an intersecting region), and when the metallization ratio of the first electrode fingers and the second electrode fingers relative to the excitation region is defined as MR, MR preferably satisfies MR≤about 1.75(d/p)+0.075, for example. In this case, it is possible to reduce the spurious response effectively.

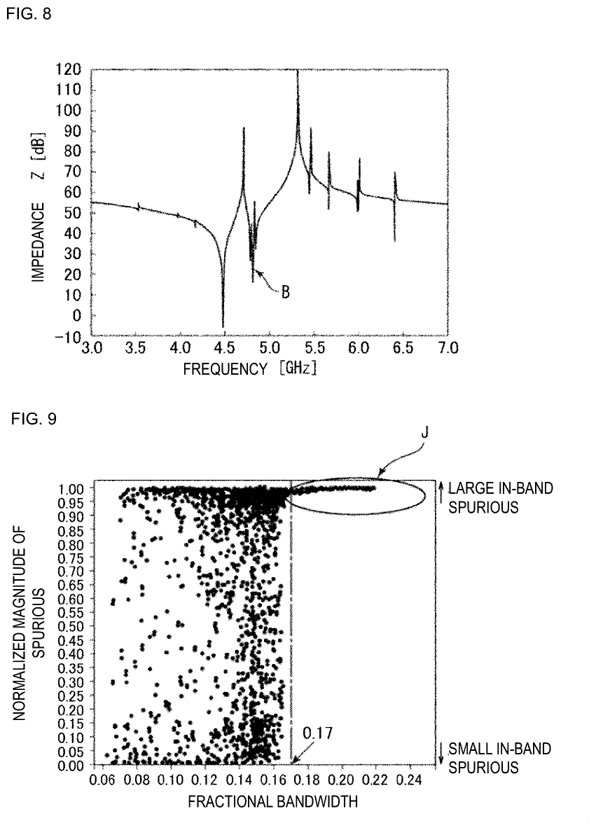

This will be described with reference to FIGS. 8 and 9. FIG. 8 is a reference diagram illustrating an example of the resonance characteristics of the acoustic wave device 1. A spurious response indicated by an arrow B emerges between a resonant frequency and an anti-resonant frequency. Here, d/p was set equal to about 0.08 and the Euler angles of the LiNbO₃ were set to (0°, 0°, 90°). Meanwhile, the aforementioned metallization ratio was set to MR=about 0.35.

The metallization ratio MR will be described with reference to FIG. 1B. When focusing on a pair of the electrodes 3 and 4 in the electrode structure of FIG. 1B, it is assumed that only this pair of electrodes 3 and 4 are provided therein. In this case, a portion surrounded by a dot-dash line C will be the excitation region. This excitation region is a region of the electrode 3 overlapping the electrode 4, a region of the electrode 4 overlapping the electrode 3, and a region between the electrode 3 and the electrode 4 where the electrode 3 and the electrode 4 overlap when the electrode 3 and the electrode 4 are viewed in the direction orthogonal or substantially orthogonal to the length direction of the electrodes 3 and 4, that is to say, in the direction in which the electrodes 3 and 4 face each other. Moreover, the area of the electrodes 3 and 4 in the excitation region C relative to the area of this excitation region is the metallization ratio MR. In other words, the metallization ratio MR is a ratio of the area of the portion of metallization relative to the area of the excitation region.

Here, when two or more pairs of the electrodes are provided, the ratio of the metallization portions included in the entire excitation region relative to a sum of the areas of the excitation regions may be defined as MR.

FIG. 9 is a diagram illustrating a relationship between a fractional bandwidth and a phase rotation amount of impedance of a spurious response normalized by about 180 degrees as magnitude of the spurious response when a large number of acoustic wave resonators are provided in accordance with the present example embodiment. Here, the fractional bandwidth was adjusted by variously changing a film thickness of the piezoelectric layer and dimensions of the electrodes. Although FIG. 9 represents a result in a case in which the piezoelectric layer made Z-cut LiNbO₃ is used, a case where the piezoelectric layer of a different cut-angle is used also shows a similar tendency.

The spurious response grows as large as about 1.0 in a region surrounded by an ellipse J in FIG. 9. As apparent from FIG. 9, when the fractional bandwidth exceeds about 0.17, or in other words, when the fractional bandwidth exceeds about 17%, the large spurious response at a spurious level equal to or greater than about 1 emerges in a pass band even when parameters defining the fractional bandwidth are changed. Specifically, as in the resonance characteristics depicted in FIG. 8, the large spurious response indicated by the arrow B occurs in the band. Therefore, the fractional bandwidth is, for example, preferably equal to or less than about 17%. In this case, the spurious response can be reduced by adjusting the film thickness of the piezoelectric layer 2, the dimensions of the electrodes 3 and 4, and the like.

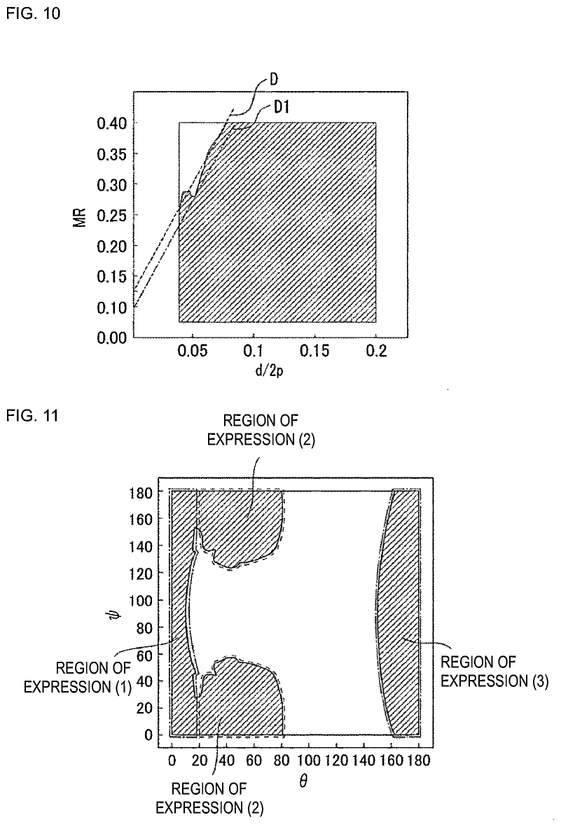

FIG. 10 is a diagram illustrating a relationship among d/2p, the metallization ratio MR, and the fractional bandwidth. Regarding the above-described acoustic wave device, various acoustic wave devices having different values of d/2p and MR are constructed and fractional bandwidths thereof were measured. A hatched portion to the right of a dashed line D in FIG. 10 is a region where the fractional bandwidth is equal to or less than about 17%. A boundary between the hatched region and a non-hatched region is expressed by MR=about 3.5(d/2p)+0.075, for example. In other words, MR=about 1.75 (d/p)+0.075 is satisfied. Accordingly, for example, MR≤about 1.75 (d/p)+0.075 is preferable. In this case, it is easier to set the fractional bandwidth equal to or less than about 17%. For example, a region to the right of MR=about 3.5(d/2p)+0.05 indicated by a dot-dash line D1 in FIG. 10 is more preferable. In other words, the fractional bandwidth can reliably be set equal to or less than about 17% when, for example, MR≤about 1.75 (d/p)+0.05 is satisfied.

FIG. 11 is a diagram illustrating a map of the fractional bandwidth relative to Euler angles (0°, θ, ψ) of LiNbO₃ when d/p is as close to 0 as possible. Hatched portions in FIG. 11 are regions where the fractional bandwidth at least equal to or greater than about 5% is obtained, for example. When ranges of the regions are approximated, the ranges are expressed by Expression (1), Expression (2), and Expression (3) below.

$$( 0 ° \pm 10 ° , 0 ° to 20 ° , any ψ ) \qquad Expression ( 1 )$$

$$( 0 ° \pm 10 ° , 20 ° to 80 ° , \\ 0 ° to 60 {° ( 1 - {( θ - 50 )}^{2} / 900 )}^{1 / 2} ) \text{} or ( 0 ° \pm 10 ° , \\ 20 ° to 80 ° , [ 180 ° - 60 {° ( 1 - {( θ - 50 )}^{2} / 900 )}^{1 / 2} ] to 180 ° ) \qquad Expression ( 2 )$$

$$( 0 ° \pm 10 ° , [ 180 ° - 30 {° ( 1 - {( ψ - 90 )}^{2} / 8100 )}^{1 / 2} ] to 180 ° , \\ any ψ ) \qquad Expression ( 3 )$$

Accordingly, the range of Euler angles represented by Expression (1), Expression (2), or Expression (3) above is preferable because the fractional bandwidth can be sufficiently widened.

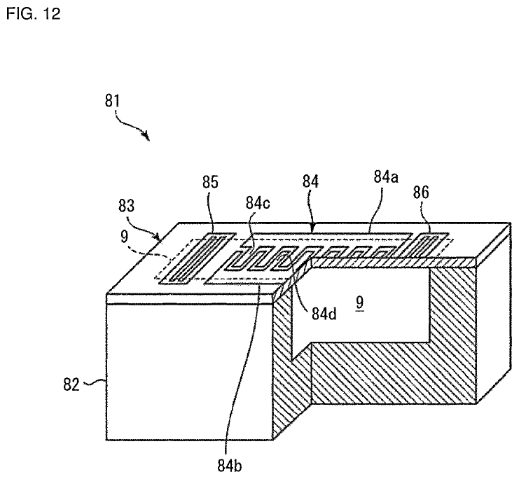

FIG. 12 is a partial cutout perspective view for explaining the acoustic wave device according to the first example embodiment of the present invention. An acoustic wave device 81 includes a support substrate 82. A recess that is open upward is provided in the support substrate 82. A piezoelectric layer 83 is laminated on the support substrate 82, such that the hollow portion 9 is provided. An IDT electrode 84 is provided above the hollow portion 9 and on the piezoelectric layer 83. Reflectors 85 and 86 are provided on both sides in a direction of acoustic wave propagation of the IDT electrode 84. An outer peripheral edge of the hollow portion 9 is indicated by a dashed line in FIG. 12. Here, the IDT electrode 84 includes first and second busbars 84a and 84b, electrodes 84c as multiple first electrode fingers, and electrodes 84d as multiple second electrode fingers. The multiple electrodes 84c are connected to the first busbar 84a. The multiple electrodes 84d are connected to the second busbar 84b. The multiple electrodes 84c and the multiple electrodes 84d are interdigitated with one another.

In the acoustic wave device 81, the Lamb wave as the plate wave is excited by applying an alternating-current electric field to the IDT electrode 84 above the hollow portion 9. Then, since the reflectors 85 and 86 are provided on both sides, it is possible to obtain the resonance characteristics attributed to the Lamb wave.

As described above, an acoustic wave device according to an example embodiment of the present invention may be configured to use the plate wave.

### Second Example Embodiment

An acoustic wave device of a second example embodiment of the present invention will be described. In the second example embodiment, explanations of contents overlapping with those in the first example embodiment will be omitted as appropriate. The second example embodiment can apply the contents described in the first example embodiment.

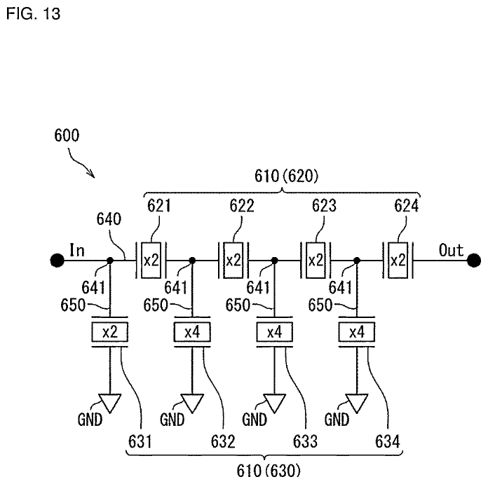

A problem of an acoustic wave device of the related art will be described. FIG. 13 is a circuit diagram of an acoustic wave device of the related art.

For example, an acoustic wave device 600 including a circuit as illustrated in FIG. 13 includes multiple acoustic wave resonators 610 including one or more series arm resonators 620 and one or more parallel arm resonators 630. In FIG. 13, the acoustic wave device includes eight acoustic wave resonators 610 including four series arm resonators 621, 622, 623, and 624, and four parallel arm resonators 631, 632, 633, and 634. Each of the series arm resonators 621, 622, 623, and 624 is disposed on a series arm 640 that is electrically connected between an input terminal In and an output terminal Out. Each of the parallel arm resonators 631, 632, 633, and 634 is disposed at least on one parallel arm 650 (which are four in FIG. 13) to be electrically connected between a node 641 on the series arm 640 and a ground potential GND.

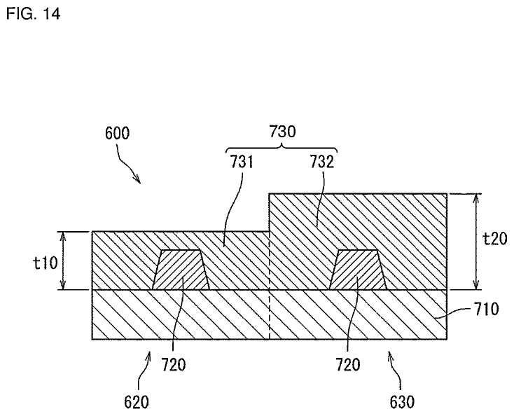

FIG. 14 is a cross-sectional view schematically illustrating a layer structure of a portion of an acoustic wave resonator in the acoustic wave device of the related art. As illustrated in FIG. 14, the acoustic wave device 600 includes a piezoelectric layer 710, a comb-shaped interdigital transducer (IDT) electrode 720 laminated on the piezoelectric layer 710, and a dielectric film 730 laminated on the piezoelectric layer 710 to cover the IDT electrode 720. Each acoustic wave resonator 610 includes the IDT electrode 720. The dielectric film 730 includes a series dielectric film 731 defined by a portion of the series arm resonator 620, and a parallel dielectric film 732 defined by a portion of the parallel arm resonator 630.

In the acoustic wave device 600 of the related art, a thickness t10 of the series dielectric film 731 is different from a thickness t20 of the parallel dielectric film 732. In FIG. 14, the thickness t10 is smaller than the thickness t20. A difference in frequency between the series arm resonator 620 and the parallel arm resonator 630 is achieved by using the difference in thickness between the dielectric films 730 laminated on the piezoelectric layer 710.

However, a difference in amount of frequency variation (such as an amount of frequency drop) is generated between the series arm resonator 620 and the parallel arm resonator 630 due to moisture absorption by the dielectric film 730 in a humid environment. Specifically, an amount of variation on a low-pass side is increased. In the case of the configuration illustrated in FIG. 14, the amount of frequency variation of the parallel arm resonator 630 with the large thickness t20 of the dielectric film 730 (the parallel dielectric film 732) is larger than the amount of frequency variation of the series arm resonator 620 with the small thickness t10 of the dielectric film 730 (the series dielectric film 731). As a consequence, impedance mismatching is caused in a pass band of a filter waveform, which leads to deterioration of in-band passage losses.

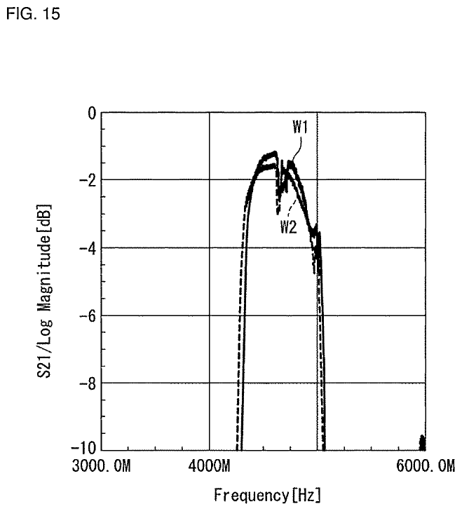

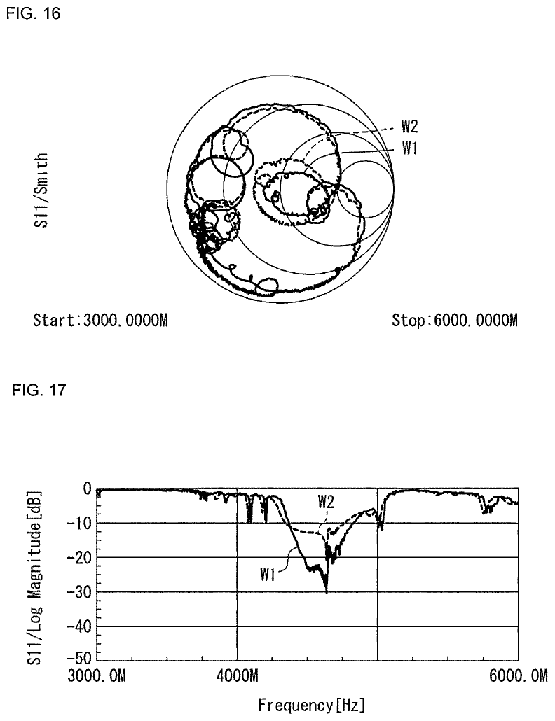

FIG. 15 is a graph depicting log magnitude relative to a frequency in the acoustic wave device of the related art. FIG. 16 is a Smith chart regarding the acoustic wave device of the related art. FIG. 17 is a graph depicting the log magnitude relative to the frequency in the acoustic wave device of the related art. Reference sign S21 indicated in FIG. 15 represents a passage loss of electric power from the input terminal In to the output terminal Out of the acoustic wave device illustrated in FIG. 13. Reference sign S11 indicated in FIGS. 16 and 17 represents a reflection coefficient on the input terminal In side of the acoustic wave device illustrated in FIG. 13.

As illustrated in FIGS. 15 to 17, a return loss in a pass band of a post-humidity test waveform W2 is deteriorated as compared to that of an initial waveform (a pre-humidity test waveform) W1. In other words, an in-band passage loss of the post-humidity test waveform is deteriorated as compared to an in-band passage loss of the initial waveform. For example, as illustrated in FIG. 15, the post-humidity test waveform W2 has a larger passage loss of the electric power from the input terminal In to the output terminal Out as compared to that of the initial waveform W1. Meanwhile, as illustrated in FIG. 16, the post-humidity test waveform W2 has a larger resistance circuit plotted on the Smith chart as compared to that of the initial waveform W1. In the meantime, as illustrated in FIG. 17, the reflection coefficient on the input terminal In side of the post-humidity test waveform W2 is small as compared to that of the initial waveform W1.

The acoustic wave device of the second example embodiment of the present invention can reduce the difference in amount of frequency variation between the series arm resonator and the parallel arm resonator attributed to the moisture absorption by the dielectric film as compared to the above-mentioned configuration of the related art.

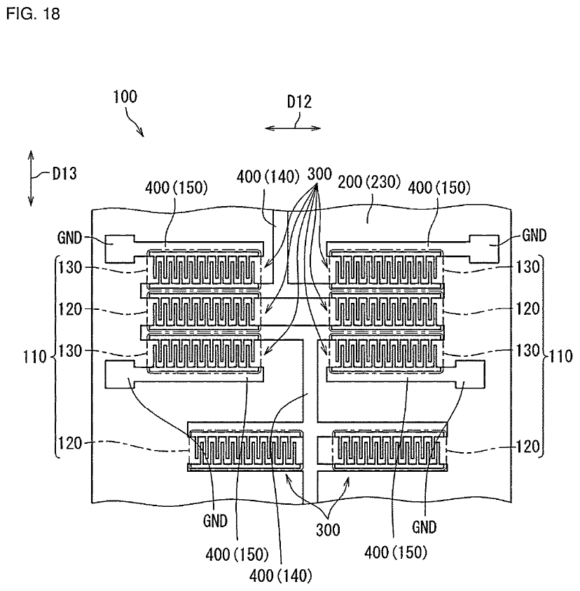

FIG. 18 is a schematic plan view of the acoustic wave device according to the second example embodiment of the present invention.

As illustrated in FIG. 18, an acoustic wave device 100 includes multiple acoustic wave resonators 110. The acoustic wave resonators 110 are portions surrounded with dot-dash lines in FIG. 18. The multiple acoustic wave resonators 110 are electrically connected to one another with laminated electrodes 400 interposed therebetween. The acoustic wave resonators 110 include one or more series arm resonators 120 and one or more parallel arm resonators 130. Of the multiple acoustic wave resonators 110 included in the acoustic wave device 100, four series arm resonators 120 and four parallel arm resonators 130 are depicted in FIG. 18.

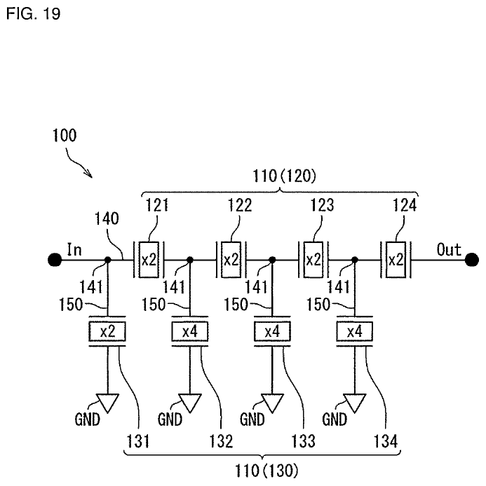

FIG. 19 is a circuit diagram of the acoustic wave device according to the second example embodiment of the present invention.

The one or more series arm resonators 120 and the one or more parallel arm resonators 130 are connected as in the circuit diagram illustrated in FIG. 19, for instance. The circuit diagram illustrated in FIG. 19 is an example which does not correspond to FIG. 18. Of the multiple acoustic wave resonators 110 included in the acoustic wave device 100, for example, four series arm resonators 120 and four parallel arm resonators 130 are depicted in FIG. 19. As illustrated in FIG. 19, the four series arm resonators 120 are disposed in series on a series arm 140 that is electrically connected between an input terminal In and an output terminal Out. Each of the four parallel arm resonators 130 is disposed on each of at least one parallel arm 150 (four in FIG. 18) electrically connected between a node 141 on the series arm 140 and a ground potential GND.

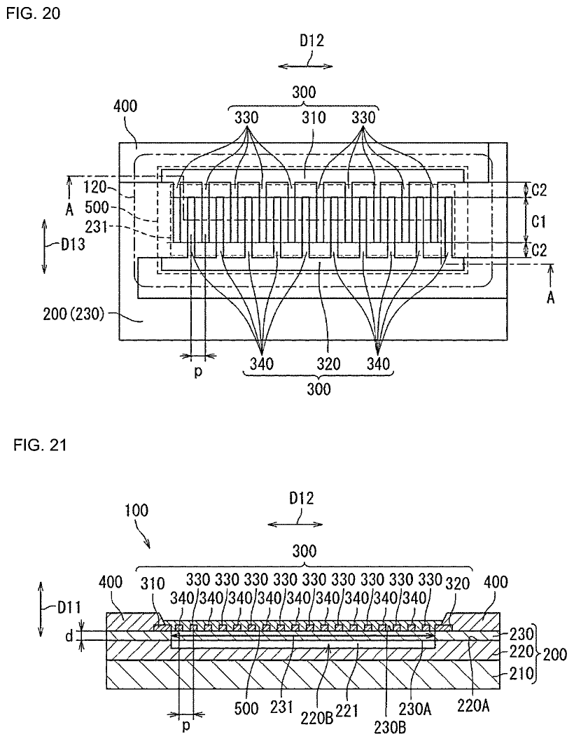

FIG. 20 is an enlarged view of a portion surrounded by a two-dot chain line in FIG. 18. FIG. 21 is a cross-sectional view schematically illustrating the acoustic wave device illustrated in FIG. 20, which is taken along the A-A line.

As illustrated in FIGS. 18, 20, and 21, the acoustic wave device 100 includes a support 200, multiple IDT (interdigital transducer) electrodes 300, the laminated electrodes 400, and a dielectric film 500. The support 200, the multiple IDT electrodes 300, the laminated electrodes 400, and the dielectric film 500 are laminated in a direction of lamination D11. The direction of lamination D11 is equivalent to a thickness direction of the acoustic wave device 100 and is an example of a first direction. Illustration of the dielectric film 500 is omitted in FIGS. 18 and 20, and a range where the dielectric film 500 is provided is indicated by a dashed line in FIG. 20.

The multiple IDT electrodes 300 are laminated on the support 200. The laminated electrode 400 is laminated on the support 200 and is electrically connected to the multiple IDT electrodes 300. Thus, the multiple IDT electrodes 300 are electrically connected to one another with the laminated electrode 400. The dielectric film 500 is laminated on the support 200.

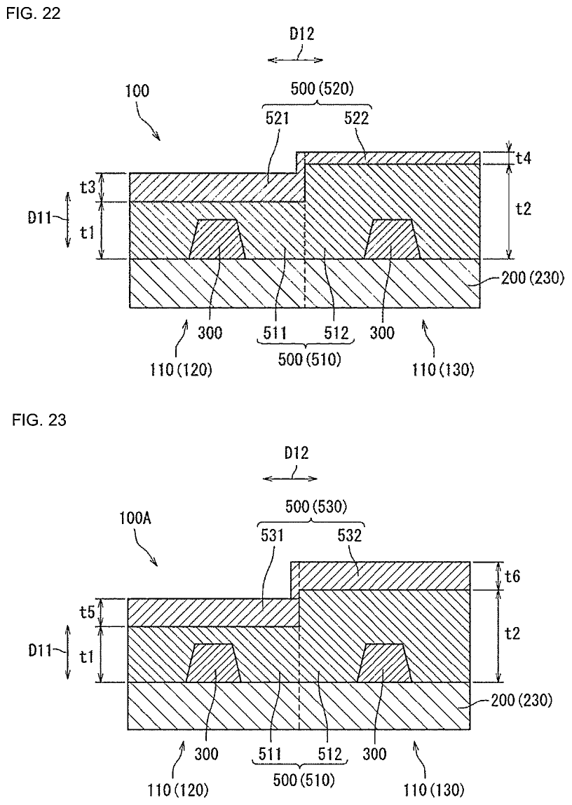

Each of the acoustic wave resonators 110 includes one IDT electrode 300, and the support 200 in addition to the dielectric film 500 located in a region overlapping the one IDT electrode 300 when viewed in the direction of lamination D11 (in other words, in plan view in the direction of lamination D11) and in a region in the vicinity of the aforementioned region (see FIG. 22 to be described later).

As illustrated in FIG. 18, a portion of the laminated electrodes 400 connecting the multiple IDT electrodes 300 in series defines the series arm 140. A portion of the laminated electrodes 400 connecting the IDT electrodes 300 to the ground potential GND defines parallel arms 150.

As illustrated in FIG. 21, the support 200 includes a support substrate 210, a joining layer 220 laminated on the support substrate 210, and a piezoelectric layer 230 laminated on the joining layer 220. Each of the support substrate 210, the joining layer 220, and the piezoelectric layer 230 has a thickness in the direction of lamination D11. The joining layer 220 is provided on the piezoelectric layer 230 side of the support substrate 210. The piezoelectric layer 230 is provided in the direction of lamination D11 of the support 200. The support substrate 210 corresponds to the support substrate 8 of the first example embodiment. The joining layer 220 corresponds to the insulating layer 7 of the first example embodiment, and is an example of an intermediate layer. The piezoelectric layer 230 corresponds to the piezoelectric layer 2 of the first example embodiment.

In the second example embodiment, for example, the support substrate 210 is made of silicon (Si), the joining layer 220 is made of silicon oxide (SiOx), and the piezoelectric layer 230 is made of lithium niobate (LN, LiNbOx). The materials of the respective portions defining the support 200 are not limited to the aforementioned materials. For example, the piezoelectric layer 230 may be made of lithium tantalate (LiTaOx) instead.

The joining layer 220 includes a recess 221. The recess 221 is recessed in the direction of lamination D11 from a principal surface 220A of the joining layer 220. A space defined by the recess 221 and another principal surface 230A of the piezoelectric layer 230 defines a hollow portion 220B. The hollow portion 220B is an example of a space portion.

The piezoelectric layer 230 is laminated on the joining layer 220. The other principal surface 230A of the piezoelectric layer 230 is in contact with the principal surface 220A of the joining layer 220. The piezoelectric layer 230 occludes the recess 221 of the joining layer 220. That is to say, the piezoelectric layer 230 is provided on the joining layer 220 so as to cover the hollow portion 220B.

As illustrated in FIGS. 20 and 21, the piezoelectric layer 230 includes a membrane 231. The membrane 231 is a portion of the piezoelectric layer 230 which overlaps the hollow portion 220B in plan view in the direction of lamination D11. In other words, the membrane 231 is a portion of the piezoelectric layer 230 which is not in contact with the principal surface 220A of the joining layer 220 in plan view in the direction of lamination D11. The hollow portion 220B can also be referred to as a space defined by the recess 221 and the membrane 231. In FIG. 20, the membrane 231 is a region of the piezoelectric layer 230 surrounded by a dashed line.

A shape of the membrane 231 in plan view in the direction of lamination D11 depends on a shape of the hollow portion 220B. The shapes of the membrane 231 and the hollow portion 220B are not limited to the shapes illustrated in FIGS. 20, and 21.

As illustrated in FIG. 21, the IDT electrode 300 is laminated on one principal surface 230B of the piezoelectric layer 230. The one principal surface 230B is the backside of the other principal surface 230A. Here, the IDT electrode 300 may be laminated on the other principal surface 230A of the piezoelectric layer 230 instead. In this case, the other principal surface 230A corresponds to one principal surface.

As illustrated in FIGS. 20 and 21, the IDT electrode 300 includes a first busbar electrode 310 and a second busbar electrode 320 facing each other, multiple first electrode fingers 330 connected to the first busbar electrode 310, and multiple second electrode fingers 340 connected to the second busbar electrode 320. The multiple first electrode fingers 330 and the multiple second electrode fingers 340 are interdigitated with one another, and the first electrode finger 330 and the second electrode finger 340 located adjacent to each other define a pair of electrodes.

The first busbar electrode 310 corresponds to the first busbar 5 of the first example embodiment. The second busbar electrode 320 corresponds to the second busbar 6 of the first example embodiment. The first electrode finger 330 corresponds to the electrode 3 of the first example embodiment. The second electrode finger 340 corresponds to the electrode 4 of the first example embodiment.

In plan view in the direction of lamination D11, at least a portion of the IDT electrode 300 is provided on the one principal surface 230B of the piezoelectric layer 230 at a position overlapping the hollow portion 220B. In plan view in the direction of lamination D11, the first electrode fingers 330 and the second electrode fingers 340 of the IDT electrode 300 are provided at the position overlapping the hollow portion 220B in the second example embodiment.

As illustrated in FIG. 20, the multiple first electrode fingers 330 are disposed to extend from the first busbar electrode 310 in an electrode finger extension direction D13. The multiple first electrode fingers 330 are arranged at intervals in an electrode finger facing direction D12. That is to say, the first busbar electrode 310 and the multiple first electrode fingers 330 define a comb-shaped electrode.

Similarly, the multiple second electrode fingers 340 are disposed to extend from the second busbar electrode 320 in the electrode finger extension direction D13. The multiple second electrode fingers 340 are arranged at intervals in the electrode finger facing direction D12. That is to say, the second busbar electrode 320 and the multiple second electrode fingers 340 define a comb-shaped electrode.

The electrode finger facing direction D12 is a direction intersecting with the direction of lamination D11 and is a direction along the one principal surface 230B of the piezoelectric layer 230. The electrode finger extension direction D13 is a direction intersecting with the direction of lamination D11 and is a direction intersecting with the electrode finger facing direction D12. In the second example embodiment, the directions of lamination D11, the electrode finger facing direction D12, and the electrode finger extension direction D13 are orthogonal or substantially orthogonal to one another.

The multiple first electrode fingers 330 and the multiple second electrode fingers 340 are disposed to overlap one another when viewed in the electrode finger facing direction D12 (in other words, in side view in the electrode finger facing direction D12). Meanwhile, in plan view in the direction of lamination D11, the multiple first electrode fingers 330 and the multiple second electrode fingers 340 are disposed adjacent to one another. Specifically, the multiple first electrode fingers 330 and the multiple second electrode fingers 340 are alternately arranged in the electrode finger facing direction D12. The first electrode finger 330 and the second electrode finger 340 located adjacent to each other are disposed to face in the electrode finger facing direction D12, thus defining a pair of electrodes.

As described above, the IDT electrode 300 includes a pair of comb-shaped electrodes including one comb-shaped electrode provided with the first busbar electrode 310 and the multiple first electrode fingers 330 and another comb-shaped electrode provided with the second busbar electrode 320 and the multiple second electrode fingers 340. Respective comb-shaped portions of the pair of comb-shaped electrodes are interdigitated with one another. As described above, the IDT electrode 300 is the IDT electrode. That is to say, the pair of comb-shaped electrodes define the IDT electrode.

The multiple first electrode fingers 330 and the multiple second electrode fingers 340 include an excitation region C1 and gap regions C2. The excitation region C1 is a region where the first electrode fingers 330 and the second electrode fingers 340 located adjacent thereto overlap in side view in the electrode finger facing direction D12. Each gap region C2 is a region where the first electrode fingers 330 and the second electrode fingers 340 located adjacent thereto do not overlap in side view in the electrode finger facing direction D12. That is to say, regarding the multiple first electrode fingers 330, the gap region C2 is a region on the first busbar electrode 310 side relative to the excitation region C1. Meanwhile, regarding the multiple second electrode fingers 340, the gap region C2 is a region on the second busbar electrode 320 side relative to the excitation region C1.

As illustrated in FIG. 21, the laminated electrode 400 is laminated on the one principal surface 230B of the piezoelectric layer 230, the first busbar electrode 310 of the IDT electrode 300, and the second busbar electrode 320 of the IDT electrode 300. Since the laminated electrode 400 is laminated on the first busbar electrode 310 and the second busbar electrode 320, the laminated electrode 400 is electrically connected to the multiple IDT electrodes 300 as described above.

As illustrated in FIG. 21, the dielectric film 500 is laminated on the one principal surface 230B of the support 200. The dielectric film 500 covers the first electrode fingers 330 and the second electrode fingers 340 out of the IDT electrodes 300. Meanwhile, the dielectric film 500 covers a portion of the first busbar electrode 310 and a portion of the second busbar electrode 320 out of the IDT electrodes 300. Portions of the first busbar electrode 310 and the second busbar electrode 320 not covered with the dielectric film 500 are covered with the laminated electrode 400.

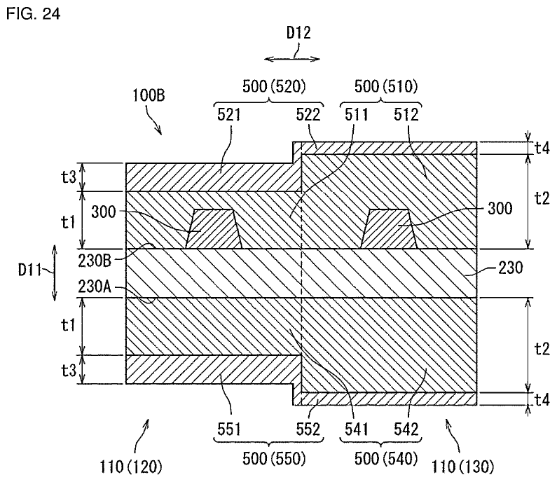

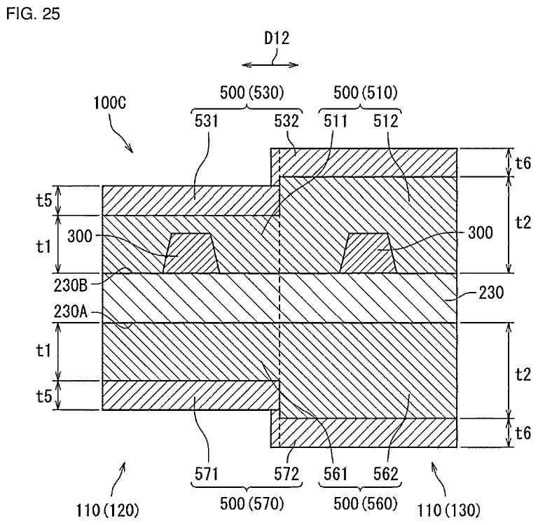

FIG. 22 is a cross-sectional view schematically illustrating a layer structure of a portion of an acoustic wave resonator in the acoustic wave device according to the second example embodiment of the present invention. FIG. 22 and FIGS. 23 to 25 to be described later illustrate a layer structure of a portion of one series arm resonator 120 and a layer structure of a portion of one parallel arm resonator 130. To be specific, the cross-sectional view schematically illustrates a region where an electrode finger on a right end of the series arm resonator 120 is located adjacent to an electrode finger on a left end of the parallel arm resonator 130. Here, in FIGS. 22 and 23 (as well as FIGS. 24 and 25 to be described later), portions illustrated as the IDT electrode 300 represent the electrode fingers (which may be any of the first electrode fingers 330 and the second electrode fingers 340) of the IDT electrode 300.

As illustrated in FIG. 22, the dielectric film 500 includes a first dielectric film 510 and a second dielectric film 520. The first dielectric film 510 is laminated on the one principal surface 230B of the piezoelectric layer 230 cover the IDT electrode 300. Here, the first dielectric film 510 may be provided between the IDT electrode 300 and the one principal surface 230B of the piezoelectric layer 230, that is to say, below the IDT electrode 300. Meanwhile, when the IDT electrode 300 is laminated on the other principal surface 230A, the first dielectric film 510 is laminated on the other principal surface 230A. In this case, the other principal surface 230A corresponds to one principal surface. The first dielectric film 510 laminated on the other principal surface 230A may cover the IDT electrode 300. The second dielectric film 520 is laminated on the first dielectric film 510.

In the second example embodiment, for example, the first dielectric film 510 is made of silicon oxide (SiO₂) and the second dielectric film 520 is made silicon nitride (SiN). That is to say, in the second example embodiment, the first dielectric film 510 is, for example, a silicon oxide film and the second dielectric film 520 is a silicon nitride film. Here, the first dielectric film 510 may be made of a material other than silicon oxide such as, for example, silicon nitride, silicon oxynitride, and tantalum pentoxide, while the second dielectric film 520 may be made of a material other than silicon nitride such as, for example, diamond, silicon, silicon nitride, aluminum nitride, and aluminum oxide.

In the second example embodiment, hygroscopicity of the second dielectric film 520 is lower than hygroscopicity of the first dielectric film 510. Here, the hygroscopicity is equivalent to a water absorption rate. The water absorption rate is a ratio of an amount of increase in weight of a dielectric film relative to its original weight when the dielectric film is soaked in distilled water for a predetermined period of time under a certain temperature.

The first dielectric film 510 includes a first series dielectric film 511 that defines a portion of the series arm resonator 120, and a first parallel dielectric film 512 that defines a portion of the parallel arm resonator 130. The first series dielectric film 511 and the first parallel dielectric film 512 have different thicknesses and configurations thereof other than the thicknesses are the same or substantially the same. The thickness of one of the first series dielectric film 511 and the first parallel dielectric film 512 is larger than the thickness of the other one of the first series dielectric film 511 and the first parallel dielectric film 512. In the second example embodiment, a thickness t2 of the first parallel dielectric film 512 is larger than a thickness t1 of the first series dielectric film 511. Here, the thickness t1 may be larger than the thickness t2 instead.

The second dielectric film 520 includes a second series dielectric film 521 that constitutes a portion of the series arm resonator 120, and a second parallel dielectric film 522 that constitutes a portion of the parallel arm resonator 130. The second series dielectric film 521 and the second parallel dielectric film 522 have different thicknesses and configurations thereof other than the thicknesses are the same. The thickness of one of the second series dielectric film 521 and the second parallel dielectric film 522 is smaller than the thickness of the other one of the second series dielectric film 521 and the second parallel dielectric film 522.

To be more precise, of the series arm resonator 120 and the parallel arm resonator 130, the resonator including the thicker first dielectric film 510 includes the thinner second dielectric film 520. In the meantime, of the series arm resonator 120 and the parallel arm resonator 130, the resonator including the thinner first dielectric film 510 includes the thicker second dielectric film 520. In the second example embodiment, the thickness t2 of the first parallel dielectric film 512 is larger than the thickness t1 of the first series dielectric film 511. That is to say, the thickness of the first dielectric film 510 of the parallel arm resonator 130 is larger than the thickness of the first dielectric film 510 of the series arm resonator 120. Accordingly, in the second example embodiment, a thickness t4 of the second parallel dielectric film 522 is smaller than a thickness t3 of the second series dielectric film 521. In other words, the thickness of the second dielectric film 520 of the parallel arm resonator 130 is smaller than the thickness of the second dielectric film 520 of the series arm resonator 120. Here, in contrast to the second example embodiment, the thickness t3 is set to be smaller than the thickness t4 when the thickness t1 is set to be larger than the thickness t2.

In the second example embodiment, by setting the respective thicknesses t1, t2, t3, and t4 as described above, it is possible to reduce the difference in amount of frequency variation (such as the amount of frequency drop) between the series arm resonator 120 and the parallel arm resonator 130 due to the moisture absorption by the dielectric film 500, which will be described below in detail.

The difference in frequency between the series arm resonator 120 and the parallel arm resonator 130 is obtained by using the difference between the thicknesses t1 and t2. In FIG. 22, the thickness t2 (the thickness in the parallel arm resonator 130) of the first parallel dielectric film 512 is larger than the thickness t1 (the thickness in the series arm resonator 120) of the first series dielectric film 511 (t2>t1).

In the first example embodiment, the second dielectric film 520 having the low hygroscopicity is provided on the first dielectric film 510 having the high hygroscopicity. In this way, the amount of frequency variation is reduced or prevented as a whole.

Meanwhile, when the thickness t2 is larger than the thickness t1, the amount of frequency variation attributed to the moisture absorption of the first parallel dielectric film 512 having the thickness t2 is larger than the amount of frequency variation attributed to the moisture absorption of the first series dielectric film 511 having the thickness t1. That is to say, the amount of frequency variation attributed to the moisture absorption in the first dielectric film 510 is larger in the parallel arm resonator 130 than in the series arm resonator 120.

Given the circumstances, the difference in amount of frequency variation is reduced in the first example embodiment by setting the thicknesses t3 and t4 in the second dielectric film 520 as described below in detail.

The configurations of the second dielectric films 520 in the series arm resonator 120 and the parallel arm resonator 130 are appropriately set based on frequency sensitivity attributed to the configurations of the second dielectric film 520, respectively, such that the amount of frequency variation after moisture absorption of the series arm resonator 120 becomes equal to that of the parallel arm resonator 130.

In contrast to the configurations of the first dielectric films 510 (the difference between the thicknesses t1 and t2), the configurations of the second dielectric films 520 are set such that the amount of frequency variation in the series arm resonator 120 is larger than that in the parallel arm resonator 130. That is to say, the thicknesses of the second series dielectric film 521 and the second parallel dielectric film 522 are set such that a magnitude relationship in thickness between the second series dielectric film 521 and the second parallel dielectric film 522 is opposite to a magnitude relationship in thickness between the first series dielectric film 511 and the first parallel dielectric film 512. Specifically, as described above, the thickness t4 of the second parallel dielectric film 522 (the thickness of the second dielectric film 520 in the parallel arm resonator 130) is smaller than the thickness t3 of the second series dielectric film 521 (the thickness of the second dielectric film 520 in the series arm resonator 120) (t4<t3).

As a consequence, the amount of frequency variation in the second dielectric film 520 in the series arm resonator 120 is larger than that in the parallel arm resonator 130. Here, as described above, the amount of frequency variation in the first dielectric film 510 in the parallel arm resonator 130 is larger than that in the series arm resonator 120. Accordingly, the thicknesses t3 and t4 are adjusted in response to the thicknesses t1 and t2 so as to reduce the difference in amount of frequency variation between the series arm resonator 120 and he parallel arm resonator 130 in total.

Here, t2>t1 and t4<t3 are satisfied in the first example embodiment. In contrast, t2<t1 and t4>t3 may be satisfied instead.

Meanwhile, composition ratios of the materials of the second series dielectric film 521 and the second parallel dielectric film 522 are the same or substantially the same in the first example embodiment. However, the composition ratios may be different as in a second dielectric film 530 of a third example embodiment of the present invention to be described below. In this case, the respective thicknesses of the second series dielectric film 521 and the second parallel dielectric film 522 are set as appropriate depending on the difference in composition ratio of the materials.

### Third Example Embodiment

FIG. 23 is a cross-sectional view schematically illustrating a layer structure of a portion of an acoustic wave resonator in an acoustic wave device according to a third example embodiment of the present invention. As with FIG. 22, FIG. 23 illustrates a layer structure of a portion of one series arm resonator 120 and a layer structure of a portion of one parallel arm resonator 130.

An acoustic wave device 100A according to the third example embodiment is different from the acoustic wave device 100 according to the second example embodiment in that the second dielectric film 530 is provided instead of the second dielectric film 520. Different features from those in the second example embodiment will be described below. Features in common to those of the acoustic wave device 100 according to the second example embodiment will be denoted by the same reference signs and explanations thereof will be basically omitted or explained when necessary.

As illustrated in FIG. 23, the acoustic wave device 100A includes the second dielectric film 530 instead of the second dielectric film 520.

The second dielectric film 530 includes a second series dielectric film 531 that defines a portion of the series arm resonator 120, and a second parallel dielectric film 532 that defines a portion of the parallel arm resonator 130. A composition ratio of materials of the second series dielectric film 531 is different from a composition ratio of materials of the second parallel dielectric film 532. A thickness t5 of the second series dielectric film 531 and a thickness t6 of the second parallel dielectric film 532 are equal or substantially equal. Except for the above-described configurations, the second dielectric film 530 has the same or substantially the same configurations as those of the second dielectric film 520.

For example, a composition percentage of silicon in one silicon nitride film of the second dielectric film 530 of the series arm resonator 120 and the second dielectric film 530 of the parallel arm resonator 130 is higher than a composition percentage of silicon in the other silicon nitride film out of the second dielectric film 530 of the series arm resonator 120 and the second dielectric film 530 of the parallel arm resonator 130.

In the third example embodiment, the composition percentage of silicon in the second dielectric film 530 of the resonator including the thick first dielectric film 510 is set to be higher than the composition percentage of silicon in the second dielectric film 530 of the resonator including the thin first dielectric film 510. Here, the thickness t2 of the first parallel dielectric film 512 of the parallel arm resonator 130 is larger than the thickness t1 of the first series dielectric film 511 of the series arm resonator 120. Accordingly, the composition percentage of silicon in the second parallel dielectric film 532 of the parallel arm resonator 130 is higher than the composition percentage of silicon in the second series dielectric film 531 of the series arm resonator 120.

The amount of frequency variation of the second dielectric film 530 becomes smaller as the composition percentage of silicon is higher and becomes larger as the composition percentage of silicon is lower. Accordingly, the amount of frequency variation in the second dielectric film 530 is larger in the series arm resonator 120 than in the parallel arm resonator 130. Here, as described above, the amount of frequency variation in the first dielectric film 510 is larger in the parallel arm resonator 130 than in the series arm resonator 120. That is to say, of the series arm resonator 120 and the parallel arm resonator 130, the composition percentage of the second dielectric film 530 is set in the resonator having the larger amount of frequency variation in the first dielectric film 510 to reduce the amount of frequency variation. This makes it possible to reduce the difference in amount of frequency variation in total by using the series arm resonator 120 and the parallel arm resonator 130.

In the third example embodiment, the composition percentage of silicon in the second parallel dielectric film 532 of the parallel arm resonator 130 is higher than the composition percentage of silicon in the second series dielectric film 531 of the series arm resonator 120. However, the present invention is not limited to this configuration. For example, when the thickness t2 of the first parallel dielectric film 512 is smaller than the thickness t1 of the first series dielectric film 511 in contrast to the above-described configurations illustrated in FIG. 22, the composition percentage of silicon in the second parallel dielectric film 532 may be set lower than the composition percentage of silicon in the second series dielectric film 531.

In the third example embodiment, for example, the second dielectric film 530 is made of silicon nitride and the composition ratios of the materials of the second series dielectric film 531 and the second parallel dielectric film 532 involve the composition percentage of silicon. However, the composition ratios of the materials are not limited to the composition ratio of silicon but may be set as appropriate depending on the materials of the second dielectric film 530.

In the third example embodiment, the thickness t5 of the second series dielectric film 531 is equal or substantially equal to the thickness t6 of the second parallel dielectric film 532. However, without limitation to the foregoing, the thickness t5 may be larger or smaller than the thickness t6. In this case, the composition ratios of the respective materials of the second series dielectric film 531 and the second parallel dielectric film 532 may be set as appropriate depending on the difference in thickness between the thicknesses t5 and t6.

### Fourth Example Embodiment

FIG. 24 is a cross-sectional view schematically illustrating a layer structure of a portion of an acoustic wave resonator in an acoustic wave device according to a fourth example embodiment of the present invention. As with FIG. 22, FIG. 24 illustrates a layer structure of a portion of one series arm resonator 120 and a layer structure of a portion of one parallel arm resonator 130.

An acoustic wave device 100B according to the fourth example embodiment is different from the acoustic wave device 100 according to the second example embodiment in that the dielectric film 500 includes a third dielectric film 540 and a fourth dielectric film 550. Different features from those in the second example embodiment will be described below. Features in common to those of the acoustic wave device 100 according to the second example embodiment will be denoted by the same reference signs and explanations thereof will be basically omitted or explained when necessary.

The third dielectric film 540 is laminated on the other principal surface 230A of the piezoelectric layer 230. In the present example embodiment, the third dielectric film 540 has the same or substantially the same configuration as that of the first dielectric film 510. For example, the third dielectric film 540 is a silicon oxide film as with the first dielectric film 510.

The fourth dielectric film 550 is laminated on the third dielectric film 540. In the present example embodiment, the fourth dielectric film 550 has the same or substantially the same configuration as that of the second dielectric film 520. For example, the fourth dielectric film 550 is a silicon nitride film as with the second dielectric film 520. Here, as with the second dielectric film 520, the fourth dielectric film 550 may be made a material other than silicon nitride such as, for example, diamond, silicon, silicon nitride, aluminum nitride, and aluminum oxide.

Hygroscopicity of the fourth dielectric film 550 is lower than hygroscopicity of the third dielectric film 540.

The third dielectric film 540 includes a third series dielectric film 541 that defines a portion of the series arm resonator 120, and a third parallel dielectric film 542 that defines a portion of the parallel arm resonator 130. The third series dielectric film 541 corresponds to the first series dielectric film 511 of the second example embodiment. The third parallel dielectric film 542 corresponds to the first parallel dielectric film 512 of the second example embodiment.

That is to say, in the present example embodiment, the third series dielectric film 541 has the same or substantially the same configuration as that of the first series dielectric film 511, and the third parallel dielectric film 542 has the same or substantially the same configuration as that of the first parallel dielectric film 512.

Meanwhile, in the present example embodiment, a relative magnitude relationship between a thickness of the third series dielectric film 541 and a thickness of the third parallel dielectric film 542 is the same or substantially the same as the relative magnitude relationship between the thickness of the first series dielectric film 511 and the thickness of the first parallel dielectric film 512. In the fourth example embodiment, the third series dielectric film 541 has the same or substantially the same thickness t1 as the first series dielectric film 511, and the third parallel dielectric film 542 has the same or substantially the same thickness t2 as the first parallel dielectric film 512. Here, these thicknesses are mere examples. That is to say, the third series dielectric film 541 may have a different thickness from that of the first series dielectric film 511, or the third parallel dielectric film 542 may have a different thickness from that of the first parallel dielectric film 512.

The fourth dielectric film 550 includes a fourth series dielectric film 551 that defines a portion of the series arm resonator 120, and a fourth parallel dielectric film 552 that defines a portion of the parallel arm resonator 130. The fourth series dielectric film 551 corresponds to the second series dielectric film 521 of the second example embodiment. The fourth parallel dielectric film 552 corresponds to the second parallel dielectric film 522 of the second example embodiment.

That is to say, in the present example embodiment, the fourth series dielectric film 551 has the same or substantially the same configuration as that of the second series dielectric film 521, and the fourth parallel dielectric film 552 has the same or substantially the same configuration as that of the second parallel dielectric film 522.

Meanwhile, a relative magnitude relationship between a thickness of the fourth series dielectric film 551 and a thickness of the fourth parallel dielectric film 552 is the same or substantially the same as the relative magnitude relationship between the thickness of the second series dielectric film 521 and the thickness of the second parallel dielectric film 522. In the fourth example embodiment, the fourth series dielectric film 551 has the same or substantially the same thickness t3 as the second series dielectric film 521, and the fourth parallel dielectric film 552 has the same or substantially the same thickness t4 as the second parallel dielectric film 522. Here, these thicknesses are mere examples. That is to say, the fourth series dielectric film 551 may have a different thickness from that of the second series dielectric film 521, or the fourth parallel dielectric film 552 may have a different thickness from that of the second parallel dielectric film 522.

Meanwhile, the thicknesses of the third dielectric film 540 and the fourth dielectric film 550 are not always different between the series arm resonator 120 and the parallel arm resonator 130. That is to say, when the acoustic wave device includes the third dielectric film 540 and the fourth dielectric film 550, the thickness of the third dielectric film 540 and the thickness of the fourth dielectric film 550 may be set arbitrarily. This also applies to a third dielectric film 560 and a fourth dielectric film 570 in a fifth example embodiment of the present invention to be described below.

### Fifth Example Embodiment

FIG. 25 is a cross-sectional view schematically illustrating a layer structure of a portion of an acoustic wave resonator in an acoustic wave device according to a fifth example embodiment of the present invention. As with FIG. 22, FIG. 25 illustrates a layer structure of a portion of one series arm resonator 120 and a layer structure of a portion of one parallel arm resonator 130.

An acoustic wave device 100C according to the fifth example embodiment is different from the acoustic wave device 100A according to the third example embodiment in that the acoustic wave device 100C includes a third dielectric film and a fourth dielectric film. Different features from those in the third example embodiment will be described below. Features in common to those of the acoustic wave device 100A according to the third example embodiment will be denoted by the same reference signs and explanations thereof will be basically omitted or explained when necessary.

The third dielectric film 560 is laminated on the other principal surface 230A of the piezoelectric layer 230. The third dielectric film 560 has the same or substantially the same configuration as that of the first dielectric film 510. For example, the third dielectric film 560 is a silicon oxide film as with the first dielectric film 510.

The fourth dielectric film 570 is laminated on the third dielectric film 560. The fourth dielectric film 570 has the same or substantially the same configuration as that of the second dielectric film 530. For example, the fourth dielectric film 570 is a silicon nitride film as with the second dielectric film 530. Here, as with the second dielectric film 530, the fourth dielectric film 570 may be made of a material other than silicon nitride such as, for example, diamond, silicon, silicon nitride, aluminum nitride, and aluminum oxide.

Hygroscopicity of the fourth dielectric film 570 is lower than hygroscopicity of the third dielectric film 560.

The third dielectric film 560 includes a third series dielectric film 561 that defines a portion of the series arm resonator 120, and a third parallel dielectric film 562 that defines a portion of the parallel arm resonator 130. The third series dielectric film 561 corresponds to the first series dielectric film 511 of the third example embodiment. The third parallel dielectric film 562 corresponds to the first parallel dielectric film 512 of the third example embodiment.

That is to say, the third series dielectric film 561 has the same or substantially the same configuration as that of the first series dielectric film 511, and the third parallel dielectric film 562 has the same or substantially the same configuration as that of the first parallel dielectric film 512.

Meanwhile, a relative magnitude relationship between a thickness of the third series dielectric film 561 and a thickness of the third parallel dielectric film 562 is the same or substantially the same as the relative magnitude relationship between the thickness of the first series dielectric film 511 and the thickness of the first parallel dielectric film 512. In the fifth example embodiment, the third series dielectric film 561 has the same or substantially the same thickness t1 as the first series dielectric film 511, and the third parallel dielectric film 562 has the same or substantially the same thickness t2 as the first parallel dielectric film 512. Here, these thicknesses are mere examples. That is to say, the third series dielectric film 561 may have a different thickness from that of the first series dielectric film 511, or the third parallel dielectric film 562 may have a different thickness from that of the first parallel dielectric film 512.

The fourth dielectric film 570 includes a fourth series dielectric film 571 that defines a portion of the series arm resonator 120, and a fourth parallel dielectric film 572 that defines a portion of the parallel arm resonator 130. The fourth series dielectric film 571 corresponds to the second series dielectric film 531 of the second example embodiment. The fourth parallel dielectric film 572 corresponds to the second parallel dielectric film 532 of the second example embodiment.

That is to say, the fourth series dielectric film 571 has the same or substantially the same configuration as that of the second series dielectric film 531, and the fourth parallel dielectric film 572 has the same or substantially the same configuration as that of the second parallel dielectric film 532. Specifically, a composition ratio of materials of the fourth series dielectric film 571 is different from a composition ratio of materials of the fourth parallel dielectric film 572. A thickness t5 of the fourth series dielectric film 571 and a thickness t6 of the fourth parallel dielectric film 572 are equal or substantially equal. Here, the fourth series dielectric film 571 may have a different thickness from that of the second series dielectric film 531, or the fourth parallel dielectric film 572 may have a different thickness from that of the second parallel dielectric film 532.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
an input terminal;
an output terminal;
a series arm electrically connected between the input terminal and the output terminal;
at least one parallel arm electrically connected between the series arm and a ground potential; and
a plurality of acoustic wave resonators including one or more series arm resonators located at the series arm and one or more parallel arm resonators located at the parallel arm; wherein
the plurality of acoustic wave resonators include:
a support including a support substrate with a thickness in a first direction;
a piezoelectric layer located in the first direction of the support;
an interdigital transducer (IDT) electrode on one principal surface in the first direction of the piezoelectric layer;
a first dielectric film on the one principal surface of the piezoelectric layer; and
a second dielectric film on the first dielectric film;
a thickness of one of the first dielectric film of the series arm resonator and the first dielectric film of the parallel arm resonator is larger than a thickness of another one of the first dielectric film of the series arm resonator and the first dielectric film of the parallel arm resonator; and
a thickness of one of the second dielectric film of the series arm resonator and the second dielectric film of the parallel arm resonator is smaller than a thickness of another one of the second dielectric film of the series arm resonator and the second dielectric film of the parallel arm resonator.

2. An acoustic wave device comprising:
an input terminal;
an output terminal;
a series arm electrically connected between the input terminal and the output terminal;
at least one parallel arm electrically connected between the series arm and a ground potential; and
a plurality of acoustic wave resonators including one or more series arm resonators located at the series arm and one or more parallel arm resonators located at the parallel arm; wherein
the plurality of acoustic wave resonators include:
a support including a support substrate with a thickness in a first direction;
a piezoelectric layer located in the first direction of the support;
an interdigital transducer (IDT) electrode on one principal surface in the first direction of the piezoelectric layer;
a first dielectric film on the one principal surface of the piezoelectric layer; and
a second dielectric film on the first dielectric film;
a thickness of one of the first dielectric film of the series arm resonator and the first dielectric film of the parallel arm resonator is larger than a thickness of another one of the first dielectric film of the series arm resonator and the first dielectric film of the parallel arm resonator; and
a composition ratio of the second dielectric film of the series arm resonator is different from a composition ratio of the second dielectric film of the parallel arm resonator.

3. The acoustic wave device according to claim 1, further comprising:
a third dielectric film on another principal surface in the first direction of the piezoelectric layer; and
a fourth dielectric film on the third dielectric film.

4. The acoustic wave device according to claim 3, wherein
a thickness of one of the third dielectric film of the series arm resonator and the third dielectric film of the parallel arm resonator is larger than a thickness of another one of the third dielectric film of the series arm resonator and the third dielectric film of the parallel arm resonator; and
a thickness of one of the fourth dielectric film of the series arm resonator and the fourth dielectric film of the parallel arm resonator is smaller than a thickness of another one of the fourth dielectric film of the series arm resonator and the fourth dielectric film of the parallel arm resonator.

5. The acoustic wave device according to claim 3, wherein
a thickness of one of the third dielectric film of the series arm resonator and the third dielectric film of the parallel arm resonator is larger than a thickness of another one of the third dielectric film of the series arm resonator and the third dielectric film of the parallel arm resonator; and
a composition ratio of the fourth dielectric film of the series arm resonator is different from a composition ratio of the fourth dielectric film of the parallel arm resonator.

6. The acoustic wave device according to claim 1, wherein the second dielectric film has lower hygroscopicity than the first dielectric film.

7. The acoustic wave device according to claim 3, wherein the fourth dielectric film has lower hygroscopicity than the third dielectric film.

8. The acoustic wave device according to claim 2, wherein a thickness of the second dielectric film of the series arm resonator is equal or substantially equal to a thickness of the second dielectric film of the parallel arm resonator.

9. The acoustic wave device according to claim 5, wherein a thickness of the fourth dielectric film of the series arm resonator is equal or substantially equal to a thickness of the fourth dielectric film of the parallel arm resonator.

10. The acoustic wave device according to claim 2, wherein
the second dielectric film includes a silicon nitride film; and
a composition percentage of silicon in one silicon nitride film of the second dielectric film of the series arm resonator and the second dielectric film of the parallel arm resonator is higher than a composition percentage of silicon in another silicon nitride film out of the second dielectric film of the series arm resonator and the second dielectric film of the parallel arm resonator.

11. The acoustic wave device according to claim 5, wherein
the fourth dielectric film includes a silicon nitride film; and
a composition percentage of silicon in one silicon nitride film out of the fourth dielectric film of the series arm resonator and the fourth dielectric film of the parallel arm resonator is higher than a composition percentage of silicon in another silicon nitride film out of the fourth dielectric film of the series arm resonator and the fourth dielectric film of the parallel arm resonator.

12. The acoustic wave device according to claim 1, wherein the second dielectric film includes diamond, silicon, silicon nitride, aluminum nitride, or aluminum oxide.

13. The acoustic wave device according to claim 3, wherein the fourth dielectric film includes diamond, silicon, silicon nitride, aluminum nitride, or aluminum oxide.

14. The acoustic wave device according to claim 1, wherein the first dielectric film includes a silicon oxide film.

15. The acoustic wave device according to claim 3, wherein the third dielectric film includes a silicon oxide film.

16. The acoustic wave device according to claim 1, wherein the support includes a space portion at a position at least partially overlapping the IDT electrode in plan view in the first direction.

17. The acoustic wave device according to claim 1, wherein the support includes an intermediate layer on a piezoelectric layer side of the support substrate.

18. The acoustic wave device according to claim 1, wherein
the IDT electrode includes a plurality of first electrode fingers included in one of a pair of comb-shaped electrodes, and a plurality of second electrode fingers included in another one of the pair of comb-shaped electrodes; and
the plurality of first electrode fingers and the plurality of second electrode fingers are alternately provided.

19. The acoustic wave device according to claim 18, wherein d/p is equal to or less than about 0.5, where a film thickness of the piezoelectric layer is defined as d and a center-to-center distance between a first electrode finger and a second electrode finger located adjacent to each other among the first electrode fingers and the second electrode fingers is defined as p.

20. The acoustic wave device according to claim 19, wherein the d/p is equal to or less than about 0.24.

21. The acoustic wave device according to claim 18, wherein, where a film thickness of the piezoelectric layer is defined as d and a center-to-center distance between a first electrode finger and a second electrode finger located adjacent to each other among the first electrode fingers and the second electrode fingers is defined as p, and a metallization ratio being a ratio of a total area of an area of the first electrode finger and an area of the second electrode finger in an excitation region relative to an area of the excitation region being a region where the first electrode finger and the second electrode finger overlap when viewed in a direction in which the plurality of first electrode fingers and the plurality of second electrode fingers are arranged is defined as MR, MR≤about 1.75×(d/p)+0.075 is satisfied.

22. The acoustic wave device according to claim 1, wherein the piezoelectric layer includes lithium niobate or lithium tantalate.

23. The acoustic wave device according to claim 22, wherein Euler angles (φ, θ, ψ) of the lithium niobate or the lithium tantalate fall within a range defined by Expression (1), Expression (2), or Expression (3):
(0°±10°, 0° to 20°, any ψ) Expression (1);
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2); and
(0°±10°, [180°−30° (1−(ψ−90)²/8100)^{1/2}] to 180°, any ψ) Expression (3).

24. The acoustic wave device according to claim 1, wherein the acoustic wave device is configured to generate a thickness-shear mode bulk wave as a dominant wave.

25. The acoustic wave device according to claim 1, wherein the acoustic wave device is configured to generate a plate wave as a dominant wave.
